(19) United States
(12) Patent Application Publication
(10) Pub. No.: US 2013/0194767 A1
(43) Pub. Date: Aug. 1, 2013

(54) MULTI-INDUCTOR USABLE WITH SLIM FLAT IMAGE DISPLAY APPARATUS

(71) Applicant: Jeong-il KANG, Yongin-si (KR)

(72) Inventor: Jeong-il KANG, Yongin-si (KR)

(73) Assignee: SAMSUNG ELECTRONICS CO., LTD., Suwon-si (KR)

(21) Appl. No.: 13/586,583

(22) Filed: Aug. 15, 2012

(30) Foreign Application Priority Data
Jan. 31, 2012 (KR) 10-2012-0010052

(51) Int. Cl. H01F 27/28; H05K 7/06

(52) U.S. Cl. 361/782; 336/170

(57) ABSTRACT

A multi-inductor usable with a slim flat image display apparatus which includes an outer core with a number of through holes formed therein in a horizontal direction; a corresponding number of inner cores provided in respective through holes; a number of windings wound around a respective inner core; a number of electrode leads which project from a bottom surface of the outer core perpendicular to central axes of the through holes. The plurality of electrode are electrically connected with opposite ends of each of the windings. The multi-inductor further includes a sealing member that fixes each of the inner cores to a respective through hole of the outer core.

### CROSS-REFERENCE TO RELATED APPLICATIONS

This application claims the benefit of priority under 35 U.S.C. §119(a) from Korean Patent Application No. 2012-10052 filed Jan. 31, 2012 in the Korean Intellectual Property Office, the disclosure of which is incorporated herein by reference in its entirety.

### BACKGROUND

1. Field

The present disclosure relates to an inductor usable with an image display apparatus. More particularly, the present disclosure relates to a thin multi-inductor usable with a slim flat image display apparatus.

2. Description of the Related Art

Generally, a slim flat image display apparatus, such as a light-emitting diode (LED) television, an organic light-emitting display (OLED) television, etc., needs electricity with low-voltage and high-current. A power supply capable supplying the low-voltage high-current electricity uses a plurality of high efficient switching power circuits that are arranged in parallel and controlled by polyphase. The switching power circuits commonly use inductors.

The inductor has high labor costs in manufacturing processes unlike general semiconductor parts. Accordingly, the inductor is the most expensive and has the largest price fluctuations among parts consisting of electronic circuits. Also, since the inductor has electrical characteristics depending on the volume thereof, the inductor has a fairly heavy weight. As a result, when the inductor is assembled on a printed circuit board, the inductor is not automatically mounted but often is manually mounted. Accordingly, if a lot of inductors are used, the productivity of the process in which the inductors are mounted on printed circuit boards becomes worse.

Since a conventional inductor having a bobbin is provided with high stiff pins formed on the bobbin, the inductor can be mounted on the printed circuit board by using a method of inserting the pins into holes of the printed circuit board. Therefore, the inductor having the bobbin is widely used in electronic products using a single side printed circuit board. For improving productivity and reducing cost of the power board, a plurality of inductors having the bobbin may be integrated to form a single multi-inductor.

When the plurality of inductors is integrated into a single multi-inductor, having a gap between a plurality of windings prevents magnetic fluxes from being connected to each other so that each of the inductors can operate independently without magnetic coupling. FIG. 1 illustrates a single multi-inductor into which two inductors are integrated. In FIG. 1, upper portions of windings 130 and 130′ are cut for convenience of explanation and clarification of the drawing.

As illustrated in FIG. 1, the multi-inductor 100 formed of two inductors 101 and 102 may be designed by a side-gap method of giving gaps D to both legs 112 and 112′ of cores 110 and 110′. However, the structure has problems that the durability of the cores 110 and 110′ is low and the level of electromagnetic noise is high.

As another example, for solving the problems of the side-gap method, two inductors 201 and 202 may be integrated as illustrated in FIG. 2. In other words, the two inductors 201 and 202 are designed to have a structure of giving gaps E to center legs 212, 212′, 222 and 222′ of the cores 210, 210′ and 220. However, the structure has problems that since the number and types of the core parts 210, 210′ and 220 are increased, productivity thereof declines and cost thereof is increased. In FIG. 2, upper portions of windings 230 and 230′ are cut for convenience of explanation and clarification of the drawing.

Therefore, it is difficult to form a multi-inductor having a simple structure and strength from the inductors using the bobbin.

### SUMMARY

The present disclosure has been developed in order to overcome the above drawbacks and other problems associated with the conventional arrangement. An aspect of the present disclosure relates to a strong multi-inductor that cannot be easily broken,. Also, the multi-inductor may be shorter so as to be used for thin products, and smaller number of parts are used to form the multi-inductor.

The above aspects can substantially be achieved by providing a multi-inductor which may include an outer core with at least two through holes being formed therein in a horizontal direction; at least two inner cores respective provided in at least two through holes; at least two windings respectively wound around a respective core of the at least two inner cores; a plurality of electrode leads which project from a bottom surface of the outer core perpendicular to central axes of the at least two through holes, wherein the plurality of electrode leads are electrically connected with opposite ends of each of the at least two windings; and a sealing member which fixes each of the at least two inner cores to a respective through hole of the at least two through holes of the outer core.

Each of the inner cores may include a winding portion around which one of the winding is wound; and a pair of caps covering the winding portion on opposite ends.

The sealing member may be provided between an outer circumferential surface of each of the pair of caps of the inner cores and a respective through hole of the outer core.

The plurality of electrode leads may be formed by bending a metal plate.

Each of the plurality of electrode leads may include a connecting portion which is connected to an end of the bottom wall of the outer core; and a lead portion which extends perpendicular from the connecting portion.

The lead portion may be a three-dimensional element and may be formed by bending so that a cross-section of the lead portion cut perpendicular to a lengthwise direction thereof has a two-dimensional shape.

The cross-section of the lead portion may include a semi-circular shape, a triangular shape, a rectangular shape, and a pentagonal shape.

The electrode lead may include a reinforcing portion spaced apart from and extended parallel to the lead portion from the connecting portion.

The connecting portion may project outside of the outer core forming a projecting portion to which a lead end of the winding is connected.

The outer core may include an extending portion which is extended in a lengthwise direction a respective inner core of the at least two inner cores from the top wall and has a length longer than the at least two inner cores.

The outer core may further include a supporting portion which supports the extending portion.

According to yet another aspect, a slim flat image display apparatus is provided which may include a frame; an image display module provided inside the frame; a power board provided inside the frame and which supplies power to the image display module; a rear cover which covers the power board; and a multi-inductor provided on the power board and which is adjacent to an inner surface of the rear cover and has at least one feature as described above.

Other exemplary features will become apparent from the following detailed description, which, taken in conjunction with the annexed drawings, describe exemplary embodiments.

### BRIEF DESCRIPTION OF THE DRAWINGS

These and/or other aspects of the present disclosure will become apparent and more readily appreciated from the following description of exemplary embodiments, taken in conjunction with the accompanying drawings of which:

FIG. 1 is a view illustrating a related-art multi-inductor;

FIG. 2 is a view illustrating another related art multi-inductor;

FIG. 3 is a perspective view schematically illustrating a multi-inductor usable with slim flat image display apparatus according to an exemplary embodiment;

FIG. 4 is an enlarged perspective view illustrating the multi-inductor according to an exemplary embodiment such as the one shown in FIG. 3;

FIG. 5 is a sectional view illustrating a multi-inductor inner cores which are arranged parallel to electrode leads according to an exemplary embodiment;

FIG. 6 is a perspective view illustrating an electrode lead of a multi-inductor such as the one in FIG. 3 according to an exemplary embodiment;

FIG. 7 is a view illustrating examples of a cross-sectional shape that can be used as a lead portion of the electrode lead such as the one depicted in FIG. 6 according to an exemplary embodiment;

FIG. 8 is a perspective view illustrating a turned over multi-inductor usable with a slim flat image display apparatus according to an exemplary embodiment;

FIG. 9 is a perspective view schematically illustrating a slim flat image display apparatus using a multi-inductor according to an exemplary embodiment;

FIG. 10 is a partially sectional view illustrating an A portion of the slim flat image display apparatus of FIG. 9 where a power board is disposed according to an exemplary embodiment;

FIG. 11 is a view conceptually illustrating when magnetic flux is transmitted between an inner core and an outer core of a multi-inductor usable with a slim flat image display apparatus according to an exemplary embodiment;

FIG. 12 is a view conceptually illustrating when a rear cover of an image display apparatus is affected by leaked magnetic flux generated between an inner core and an outer core of a multi-inductor usable with a slim flat image display apparatus according to an exemplary embodiment;

FIG. 13 is a view conceptually illustrating when a rear cover of an image display apparatus is not affected by leaked magnetic flux generated between an inner core and an outer core of a multi-inductor usable with a slim flat image display apparatus according to an exemplary embodiment;

FIG. 14 is a perspective view schematically illustrating a multi-inductor usable with a slim flat image display apparatus according to an exemplary embodiment; and

FIG. 15 is a perspective view schematically illustrating a multi-inductor usable with a slim flat image display apparatus according to an exemplary embodiment.

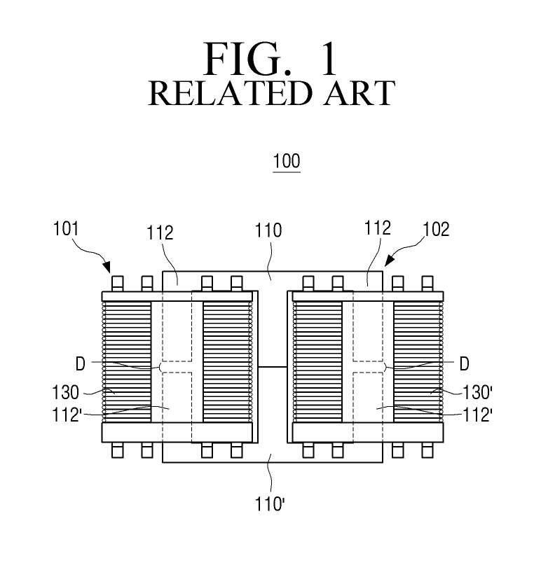

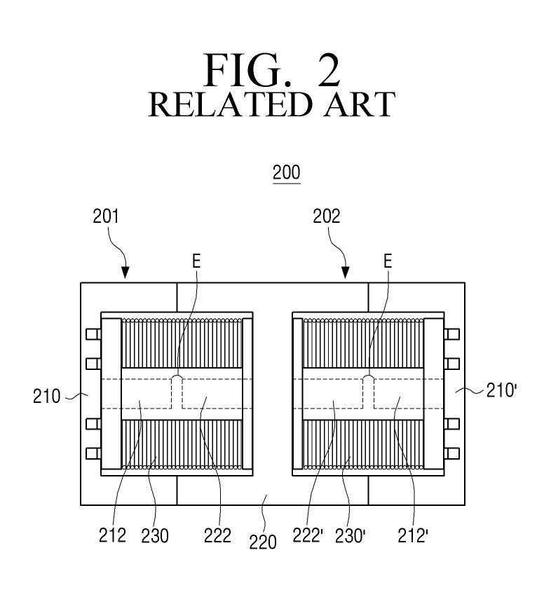

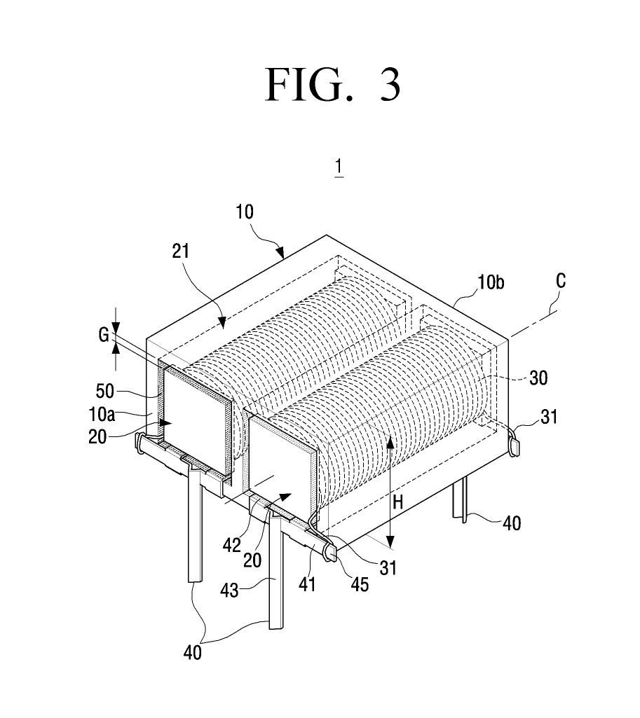

Throughout the drawings, like reference numerals will be understood to refer to like parts, components and structures.

### DETAILED DESCRIPTION OF THE EXEMPLARY EMBODIMENTS

Hereinafter, certain exemplary embodiments of the present disclosure will be described in detail with reference to the accompanying drawings.

The matters defined herein, such as a detailed construction and elements thereof, are provided to assist in a comprehensive understanding of this description. Thus, it is apparent that exemplary embodiments may be carried out without those defined matters. Also, well-known functions or constructions are omitted to provide a clear and concise description of exemplary embodiments. Further, dimensions of various elements in the accompanying drawings may be arbitrarily increased or decreased for assisting in a comprehensive understanding.

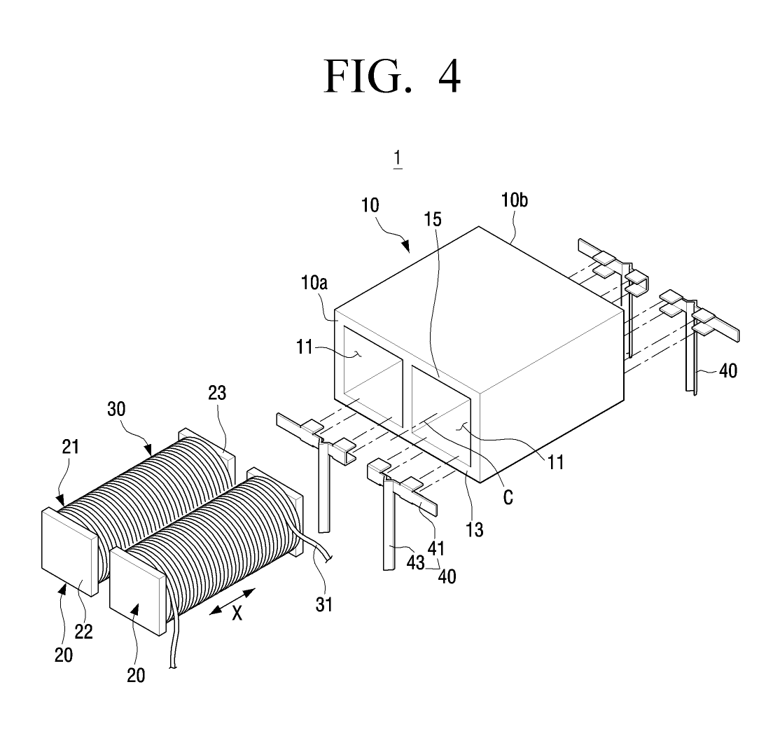

FIG. 3 is a perspective view illustrating a multi-inductor usable with slim flat image display apparatus according to an exemplary embodiment, and FIG. 4 is an enlarged perspective view illustrating the multi-inductor such as the one shown in FIG. 3.

Referring to FIGS. 3 and 4, the multi-inductor 1 according to an exemplary embodiment of the present disclosure includes an outer core 10, a plurality of inner cores 20, a plurality of windings 30 and a plurality of electrode leads 40.

The outer core 10 is substantially formed in a rectangular parallelepiped shape with a top wall 15 and a bottom wall 13. A plurality of through holes 11 is formed to penetrate a front surface 10a and a rear surface 10b between the front surface 10a and the rear surface 10b of the outer core 10. In the present exemplary embodiment as illustrated in FIGS. 3 and 4, two through holes 11 are formed on the outer core 10. The two through holes 11 are formed parallel to each other in a horizontal direction. In other words, the two through holes 11 are arranged in parallel and horizontally with respect to a bottom surface of the outer core 10. The through hole 11 may be formed to have a cross-section such as a circle or a polygon. In the present exemplary embodiment, the through hole 11 is formed to have a square cross-section. The outer core 10 may be formed of a material such as ferrite so magnetic flux generated in the windings 30 can flow smoothly.

The inner cores 20 are inserted in the through holes 11 of the outer core 10 to form a single inductor and are formed to have the number corresponding to the plurality of through holes 11. The multi-inductor 1 according to the present exemplary embodiment, as illustrated in FIGS. 3 and 4, is provided with two inner cores 20 to correspond to the two through holes 11 of the outer core 10.

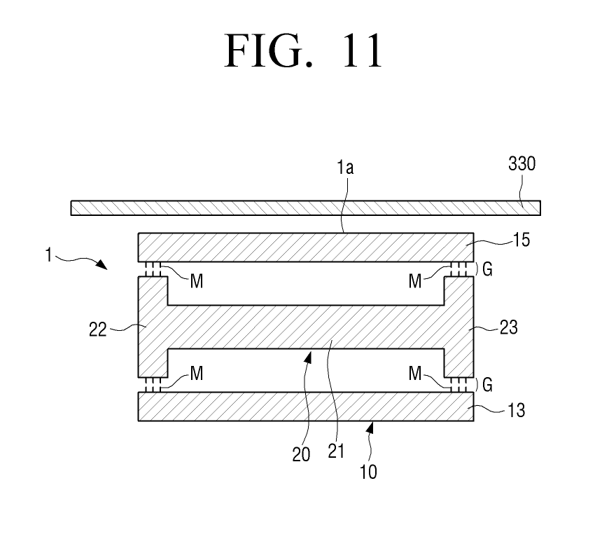

The inner core 20 is formed to have a winding portion 21(see FIGS. 11, 12 and 13 described in greater detail below) and a pair of caps 22 and 23 disposed on opposite ends of the winding portion 21. The winding portion 21 has an external circumferential surface on which a coil 31 is wound around, which may be formed in a bar shape having a circular cross-section. The pair of caps 22 and 23 are disposed on opposite ends of the winding portion 21 and have a cross-sectional area wider than that of the winding portion 21. When the inner cores 20 are disposed inside the through holes 11 of the outer core 10 (shown in FIG. 3), the pair of caps 22 and 23 guide magnetic flux generated in the inner cores 20 to the outer core 10. Accordingly, the pair of caps 22 and 23 are formed to have a shape corresponding to the cross-section of the through hole 11. In the present exemplary embodiment, the pair of caps 22 and 23 are formed as a square plate to correspond to the through hole 11 having a square cross-section. Alternatively, if the through hole 11 is formed in a circular cross-section, the pair of caps 22 and 23 are formed as a circular plate.

Also, after the inner cores 20 are inserted in the through holes 11 of the outer core 10, gaps G (shown in FIG. 3) are formed between the pair caps 22 and 23 and the through holes 11 of the outer core 10. In other words, the caps 22 and 23 of the inner cores 20 are formed in the same shape as the cross-sectional shape of the through hole 11 of the outer core 10 and to have a cross-sectional area smaller than that of the through hole 11 of the outer core 10. A sealing member 50 (shown in FIG. 3) is filled in the gaps G between the caps 22 and 23 and the through holes 11 so as to fix the inner cores 20 to the outer core 10. The sealing member 50 can provide insulation between the inner cores 20 and the outer core 10, and bond the inner cores 20 to the outer core 10. The inner cores 20 may be formed of a material such as ferrite so the magnetic flux can smoothly flow analogous to the flow in the outer core 10.

The inner cores 20 are formed to have a length so that outer surfaces of the pair of caps 22 and 23 form the substantially same plane as the front surface 10a and the rear surface 10b of the outer core 10, respectively. In other words, the inner cores 20 may be formed so that when the inner cores 20 are inserted in the through holes 11 of the outer core 10, a first cap 22 of the inner core 20 forms substantially the same plane as the front surface 10a of the outer core 10 and a second cap 23 forms the substantially same plane as the rear surface 10b of the outer core 10.

A winding is wound around the external circumferential surface of each of the plurality of inner cores 20. In other words, the coil 31 is wound in a spiral around the external circumferential surface of the winding portion 21 of the inner core 20 to form the winding 30. The winding 30 may be formed so that a long coil can be wound provided the coil does not come into contact with an inner surface of the through hole 11.

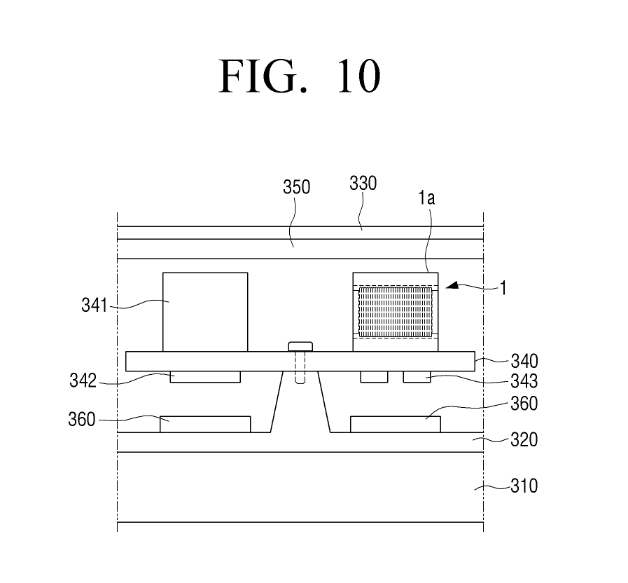

The plurality of electrode leads 40 are electrically connected to the opposite ends of the coil 31 forming the winding 30 and supply electricity to the windings 30. Accordingly, one winding 30 is provided with two electrode leads 40. Also, the plurality of electrode leads 40 connects the multi-inductor 1 according to an exemplary embodiment to a printed circuit board 340 (see FIG. 10) and connects the windings 30 of the multi-inductor 1 to circuits formed on the printed circuit board 340.

The plurality of electrode leads 40 are disposed to project from the bottom surface of the outer core 10 perpendicularly with respect to a central axis C of each of the plurality of through holes 11 formed in the outer core 10. In other words, the plurality of electrode leads 40 are positioned on opposite ends of a bottom wall 13 of the outer core 10 in a direction perpendicular to a lengthwise direction (arrow X, see FIG. 4) of the inner core 20. Accordingly, the plurality of electrode leads 40 projects downward from and perpendicular to the bottom surface of the outer core 10. In this case, a direction in which the coil 31 is wound around the inner core 20 is substantially parallel to an installation direction of the plurality of electrode leads 40.

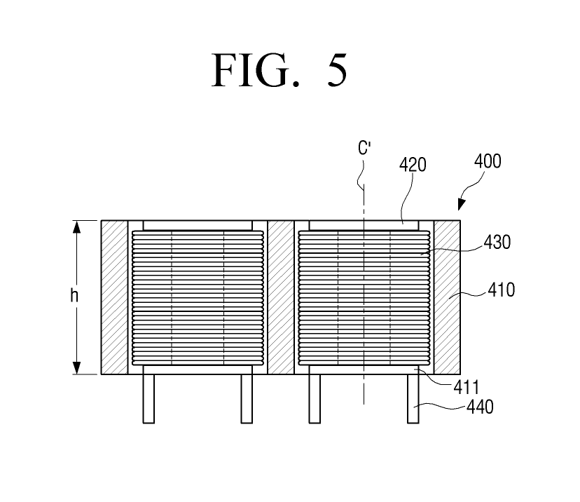

Alternatively, as illustrated in FIG. 5, a plurality of electrode leads 440 may be placed on the same surface in which the through holes 411 are formed. In this case, the plurality of electrode leads 440 are parallel to central axes C′ of a plurality of through holes 411 formed on an outer core 410. In other words, the plurality of electrode leads 440 are placed parallel to a lengthwise direction of the inner core 420. Further, a direction in which a coil of each of the windings 430 is wound around the inner core 420 is approximately perpendicular to an installation direction of the plurality of electrode leads 440. As illustrated in FIG. 5, if the multi-inductor 400 which has the plurality of electrode leads 440 positioned parallel to the through holes 411 of the outer core 410 is used in the slim flat image display apparatus, the magnetic flux leaked from between the outer core 410 and inner core 420 adjacent to an external cover of the image display apparatus is applied to the external cover, thereby generating electromagnetic interference. As a result, loss of induced currents may occur, heat may be generated, and the external cover may vibrate. Further, there is a problem that the multi-inductor 400 having the structure as illustrated in FIG. 5 has a height h higher than that of the multi-inductor 1 according to an exemplary embodiment illustrated in FIG. 3.

In an exemplary embodiment, for lowering the height H of the multi-inductor 1, the electrode leads 40 are formed by bending a plate. For conductivity and strength, the electrode leads 40 may be formed of a metal plate made of copper for example. Referring to

FIGS. 3, 4 and 6, the electrode lead 40 may be configured of a connecting portion 41 and a lead portion 43.

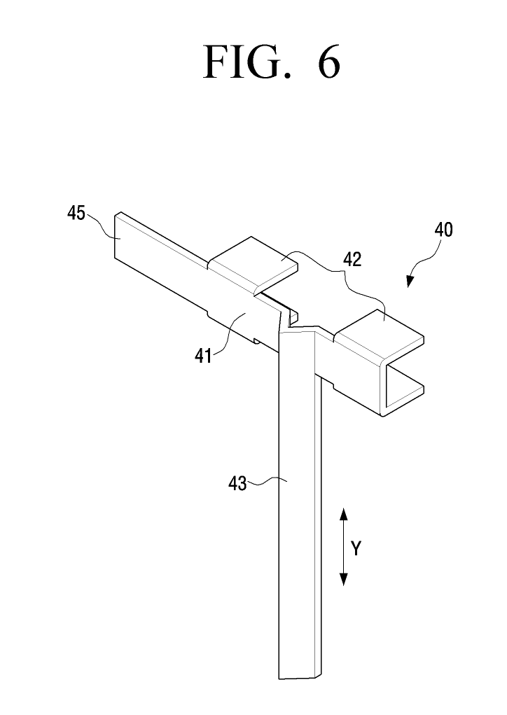

The connecting portion 41 fixes each of the electrode leads 40 to the outer core 10 and is formed to be coupled to one end of the bottom wall 13 (shown in FIG. 4) between the through hole 11 and the bottom surface of the outer core 10. Referring to FIG. 6, the connecting portion 41 includes four wings that clasp the one end of the bottom wall 13 of the outer core 10. In the present exemplary embodiment, the connecting portion 41 is formed having four wings 42; however, this is only one example. The connecting portion 41 may be formed in various shapes as long as it can couple the electrode leads 40 to the bottom wall 13 of the outer core 10. In other words, the shape and number of connection parts of the connecting portion 41 that attach to the bottom wall 13 may vary.

Further, a projecting portion 45 projecting from a side surface of the outer core 10 is formed on an end of the connecting portion 41. A lead end of the coil 31 forming the winding 30 is electrically connected to the projecting portion 45. Accordingly, if the multi-inductor 1 is mounted on a printed circuit board 340, external current flows to the winding 30 through the projecting portion 45 of the connecting portion 41.

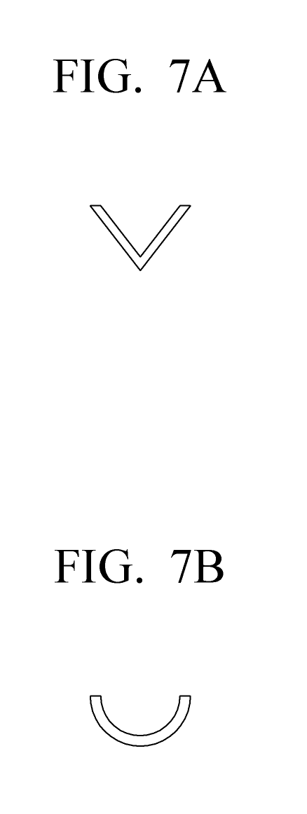

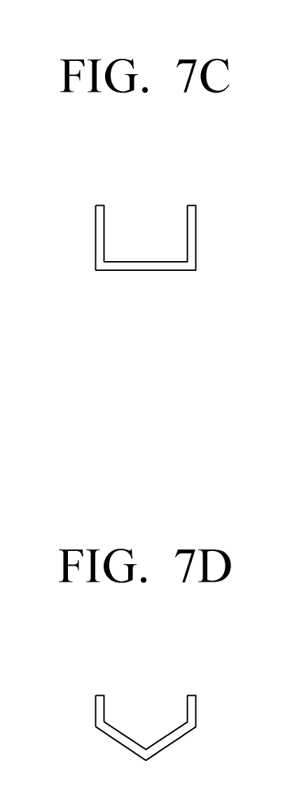

The lead portion 43 is extended perpendicular from the connecting portion 41. At this time, the lead portion 43 is formed to have a three-dimensional shape in order to increase the strength thereof. In other words, the lead portion 43 may be formed by bending so that a cross-section of the lead portion 43 cut perpendicular with respect to the lengthwise direction thereof (a Y direction in FIG. 6) has a two-dimensional shape. The lead portion 43 of the electrode lead 40 as illustrated in FIG. 6 is formed in a channel shape having a triangular cross-section. FIG. 7 illustrates cross-sections of the lead portions 43 having various shapes according to an exemplary embodiment. FIG. 7(a) illustrates a cross-section of the lead portion 43 having a triangle shape. FIG. 7(b) illustrates the cross-section of the lead portion 43 having a semi-circular shape. FIG. 7(c) illustrates the cross-section of the lead portion 43 having a rectangular shape. FIG. 7(d) illustrates the cross-section of the lead portion 43 having a pentagonal shape. FIGS. 7(a) to 7(d) illustrate only examples of cross-sections of the lead portion 43; therefore, the lead portion 43 may be formed in various cross-sectional shapes as long as they can increase the strength of the lead portion 43.

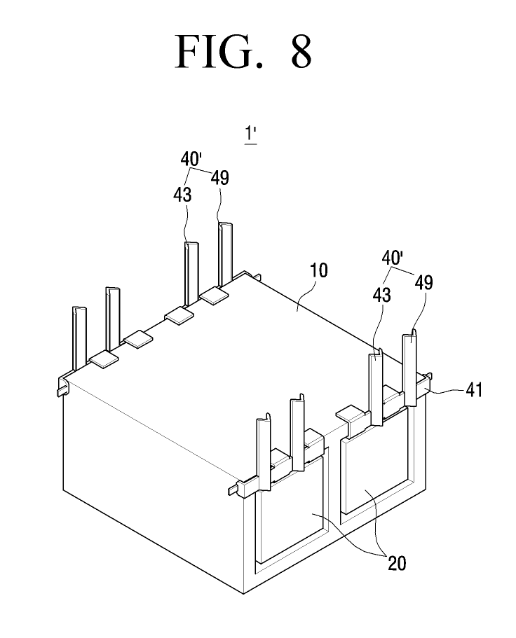

Referring to FIG. 8, the electrode leads 40′ may include a reinforcing portion 49 for increasing fixed strength of the multi-inductor V. FIG. 8 illustrates the multi-inductor 1′ which is in an overturned state in order to clearly show the electrode leads 40′. The multi-inductor 1′ has an outer core 10 and an inner core 20. The reinforcing portion 49 is formed in a similar or identical shape as the lead portion 43 and also extends from the connecting portion 41 at a certain distance away from and parallel to the lead portion 43. In FIG. 8, the lead portion 43 and the reinforcing portion 49 have a triangular cross-section. If the electrode leads 40′ are formed to include the lead portion 43 and the reinforcing portion 49, the multi-inductor 1′ is fixed to the printed circuit board 340 (shown in FIG. 10) by the lead portion 43 and the reinforcing portion 49. Accordingly, the multi-inductor 1′ having the reinforcing portion 49 is fixed to the printed circuit board 340 more firmly than the multi-inductor 1 having only lead portion 43.

Hereinafter, a slim flat image display apparatus 300 in which the multi-inductor 1 is provided according to an exemplary embodiment will be explained.

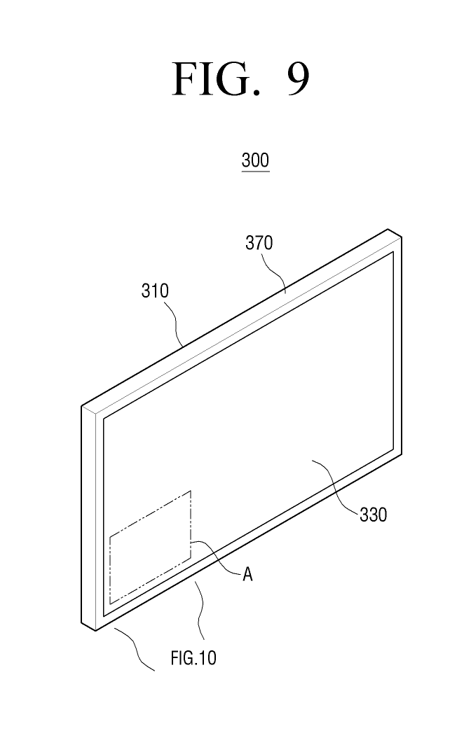

FIG. 9 is a perspective view schematically illustrating a slim flat image display apparatus where a multi-inductor according to an exemplary embodiment of the present disclosure is used, and FIG. 10 is a partially sectional view illustrating an A portion of the slim flat image display apparatus of FIG. 9 where a power board is provided according to an exemplary embodiment. In FIG. 9, the portion in which the power board is provided is only one example; therefore, the power board may be provided in various other locations according to the structure of the slim flat image display apparatus.

Referring to FIGS. 9 and 10, the slim flat image display apparatus 300 may include an image display module 310, a frame 370, a power board 340, and a rear cover 330.

The image display module 310 is a device which outputs images such as LED, OLED, etc. The image display module 310 is the same as or similar to an image display module used in a related art slim flat image display apparatus. Therefore, detailed explanations thereof will be omitted.

The frame 370 is a border of the image display apparatus 300 that is visible from the outside. The image display module 310 is disposed on a front surface of the frame 370.

The power board 340 (shown in FIG. 10) supplies electricity to the image display module 310 and is provided inside the frame 370. As illustrated in FIG. 10, the power board 340 is fixed to an inner chassis 320 provided behind the image display module 310. The inner chassis 320 is provided inside the frame 370 to support the rear surface of the image display module 310. The above-described multi-inductor 1 is mounted on the power board 340. Large parts 1 and 341 such as the multi-inductor 1 among various parts are mounted on a top surface of the power board 340 and small parts 342 and 343 there among are mounted on a bottom surface of the power board 340.

The rear cover 330 is disposed to cover a rear surface of the frame 370. Accordingly, after the rear cover 330 is provided to cover the rear surface of the frame 370, as illustrated in FIG. 10, the rear cover 330 covers the power board 340. Therefore, in the slim flat image display apparatus 300, the top surface la of the multi-inductor 1 is adjacent to the rear cover 330. For insulation between the power board 340 and the rear cover 330, a first insulating member 350 is provided on an inner surface of the rear cover 330. Also, for insulation between the power board 340 and the inner chassis 320, a second insulating member 360 is provided on a surface of the inner chassis 320 facing the power board 340.

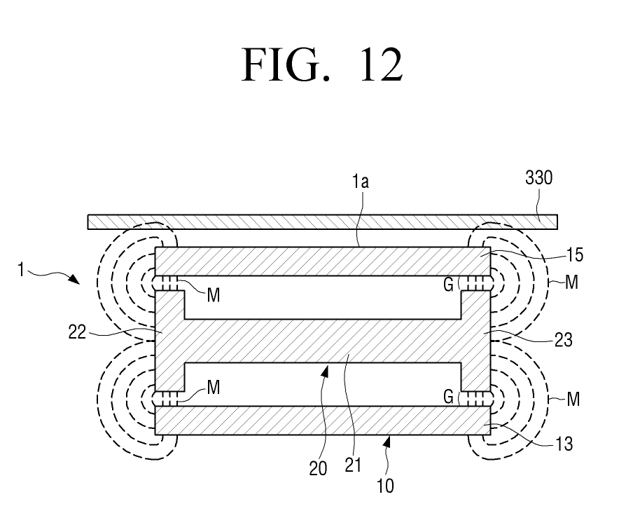

FIG. 11 illustrates a state in which the magnetic flux M goes across the gap G between the inner core 20 and the outer core 10 in the above-described multi-inductor 1. In an ideal case, as illustrated in FIG. 11, most of the magnetic flux M goes across the gap G in the shortest distance. However, this is possible only when the gap G is very narrow. In an actual case, as illustrated in FIG. 12, there is a magnetic flux M that goes beyond the gap G between the inner core 20 and the outer core 10 and goes on sides of the gap G. In FIGS. 11 and 12, the windings 30 wound around the winding portion 21 of the inner core 20 is omitted for clarification of the drawings and convenience of explanation. In FIGS. 11 and 12, the outer core 10 has a bottom wall 12 and a top wall 15. Caps 22 and 23 cover the winding portion 21.

If the magnetic flux M of the multi-inductor 1, as illustrated in FIG. 11, is ideally transmitted only through the gap G, even when the rear cover 330 is placed close to the top surface 1a of the multi-inductor 1, electromagnetic interference is not generated between the rear cover 330 and the multi-inductor 1.

Even when the magnetic flux M that is leaked beyond the gap G between the inner core 20 and the outer core 10 and goes through the side of the gap G is generated, if the rear cover 330 is formed of a plastic or a nonmetal that is not affected by magnetic force, the electromagnetic interference is not generated between the rear cover 330 and the multi-inductor 1. However, if the rear cover 330 is made of a metal, the electromagnetic interference is generated between the rear cover 330 and the multi-inductor 1 due to the leaked magnetic flux M (shown in FIG. 12). When the electromagnetic interference is generated between the rear cover 330 and the multi-inductor 1, the rear cover 330 may be vibrated so as to generate heat or/and noise.

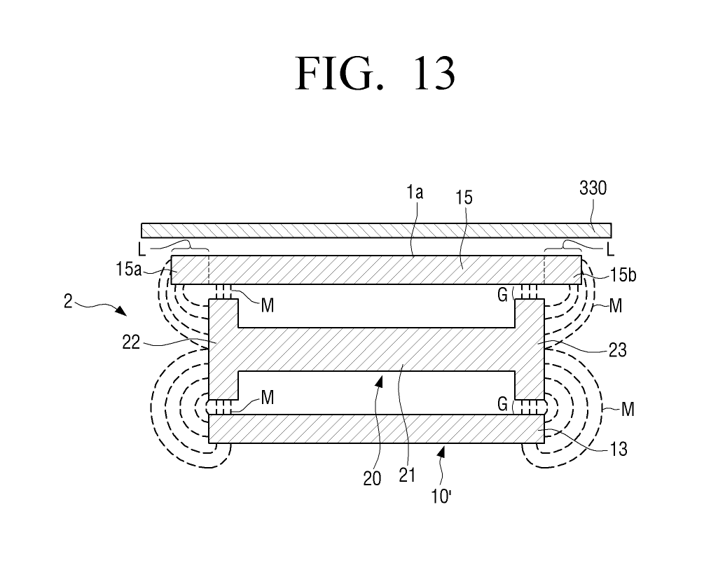

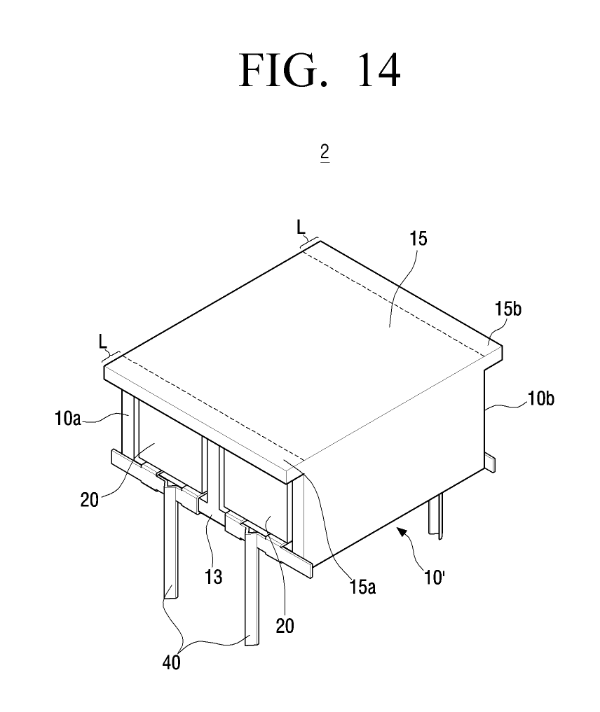

In order to prevent the electromagnetic interference between the rear cover 330 and the multi-inductor 2, in FIG. 13, a top wall 15 of the outer core 10′ of the multi-inductor 2 near the rear cover 330 may be formed to have a length longer than that of the inner core 20 inserted in the through hole 11. In other words, the top wall 15 of the outer core 10′ has a first extending portion 15a and a second extending portion 15b projecting outside from the front surface 10a and the rear surface 10b (shown in FIG. 14). The length L of each of first and second extending portions 15a and 15b projecting from each of the front surface 10a and the rear surface 10b of the outer core 10 is determined so that the leaked magnetic flux M beyond the gap G between the inner core 20 and the outer core 10, as illustrated in FIG. 13, does not affect the rear cover 330. In other words, the projecting length L of each of the first and second extending portions 15a and 15b is determined so that the leaked magnetic flux M between the outer core 10 and the inner core 20 does not generate electromagnetic interference with the rear cover 330. In another exemplary embodiment, the first and second extending portions 15a and 15b may have different lengths from each other. This may provide additional flexibility in preventing leaked magnetic flux M at each end on a per need basis and to accommodate various structural designs of the rear cover 330. In FIG. 13, the windings 30 wound around the winding portion 21 of the inner core 20 is omitted for clarification of the drawings and convenience of explanation. The inner core 20 has caps 22 and 23 and the outer core 10′ further has a bottom wall 13.

FIG. 14 illustrates one example of the multi-inductor 2 having the first and second extending portions 15a and 15b as described above according to an exemplary embodiment.

Referring to FIG. 14, the multi-inductor 2 includes an outer core 10′, two inner cores 20, and four electrode leads 40.

The outer core 10′ is formed in a substantially rectangular parallelepiped shape and is provided with two through holes 11 (not shown) passing through the front surface 10a and the rear surface 10b of the outer core 10′. The top wall 15 of the outer core 10′ has a length longer than the bottom wall 13. In other words, a first extending portion 15a extending in a lengthwise direction of the inner core 20 is provided on a front end of the top wall 15 of the outer core 10′, and a second extending portion 15b extending in a lengthwise direction of the inner core 20 is provided on a rear end of the top wall 15. Accordingly, the top wall 15 of the outer core 10′ is longer than that of the inner core 20 disposed in the through hole 11.

The two inner cores 20 and the four electrode leads 40 may be similar to the inner core 20 and electrode leads 40 of the multi-inductor 1 described above; therefore, detailed explanations thereof will be omitted.

If the first and second extending portions 15a and 15b are formed on the top wall 15 of the outer core 10′, the rear cover 330 is prevented from electromagnetic interference caused by the magnetic flux M leaked from the gap G between the inner core 20 and the outer core 10′.

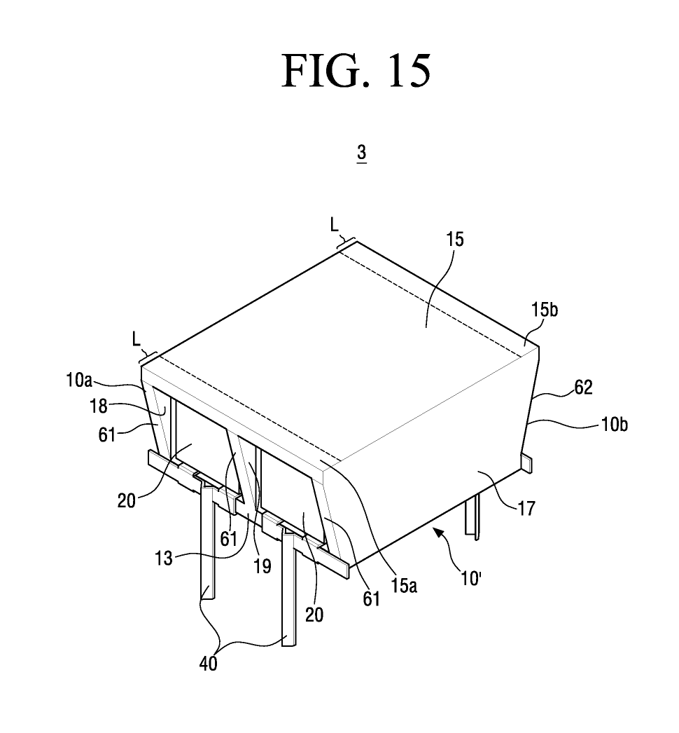

FIG. 15 is a perspective view illustrating a multi-inductor according to an exemplary embodiment of the present disclosure.

Referring to FIG. 15, the multi-inductor 3 includes an outer core 10′, two inner cores 20, four electrode leads 40, and first and second supporting portions 61 and 62.

The outer core 10′ is formed in a substantially rectangular parallelepiped shape and is provided with two through holes 11 (not shown) passing through the front surface 10a and the rear surface 10b. The top wall 15 of the outer core 10′ has a length longer than the bottom wall 13. In other words, a first extending portion 15a extending in a lengthwise direction of the inner core 20 is provided on a front end of the top wall 15 of the outer core 10′, and a second extending portion 15b extending in a lengthwise direction of the inner core 20 is provided on a rear end of the top wall 15. Accordingly, the top wall 15 of the outer core 10′ is longer than that of the inner core 20 disposed in the through hole 11.

The first and second supporting portions 61 and 62 supporting the first and second extending portions 15a and 15b, respectively, are provided on the front surface 10a and the rear surface 10b, respectively, of the outer core 10′. The first supporting portion 61 is formed in an inclined surface on the front surface 10a of the outer core 10′ to support the bottom surface of the first extending portion 15a. The first supporting portion 61 may be formed to support the first extending portion 15a at two or more locations. In the present exemplary embodiment, three first supporting portions 61 support the first extending portion 15a. The second supporting portion 62 is formed in an inclined surface on the rear surface 10b of the outer core 10′ to support the bottom surface of the second extending portion 15b. If the first and second extending portions 15a and 15b are supported by the first and second supporting portions 61 and 62, the first and second extending portions 15a and 15b projecting from the outer core 10′ may be prevented from being damaged by external force. Although the second supporting portion 62 is not illustrated, three second supporting portions 62 are formed to support the second extending portion 15b similar to the first supporting portion 61 according to an exemplary embodiment. As illustrated in FIG. 15, the first and second supporting portions 61 and 62 may be formed to be extended from opposite ends of each of both side walls 17 and 18 and a central wall 19.

The two inner cores 20 and the four electrode leads 40 may be similar to the inner core 20 and electrode leads 40 of the multi-inductor 1 described above; therefore, detailed explanations thereof will be omitted.

With a multi-inductor usable with a slim flat image display apparatus according to an exemplary embodiment of the present disclosure, since inner cores are arranged perpendicular to electrode leads, the height of the multi-inductor can be reduced compared to a multi-inductor inner cores of which are disposed parallel to the electrode leads.

Further, with a multi-inductor usable with a slim flat image display apparatus according to an exemplary embodiment of the present disclosure, since electrode leads are formed by bending a metal plate and then placed on opposite ends of a bottom wall of an outer core, the height of the multi-inductor can be reduced compared to a multi-inductor using a separate base on which electrode leads are disposed.

Further, with a multi-inductor usable with a slim flat image display apparatus according to an exemplary embodiment of the present disclosure, since an extending portion is formed on a top wall of an outer core, the multi-inductor can prevent leaked magnetic flux generated by fringing effect from electromagnetic interference with a rear cover.

While exemplary embodiments have been described, additional variations and modifications of exemplary embodiments may occur to those skilled in the art once they learn of the basic inventive concepts. Therefore, it is intended that the appended claims shall be construed to include exemplary embodiments and all such variations and modifications that fall within the spirit and scope of the inventive concepts. It is understood that all possible changes and/or modifications in form and details may be made therein without departing from the spirit and scope of an inventive concept as defined by the appended claims and their equivalents. The scope is defined not by the detailed description of exemplary embodiments but by the appended claims, and their equivalents and all differences within the scope will be construed as being included in an inventive concept.

What is claimed is:

1. A multi-inductor comprising:
an outer core with at least two through holes being formed therein in a horizontal direction;
at least two inner cores respectively provided in the at least two through holes;
at least two windings respectively wound around a respective core of the at least two inner cores;
a plurality of electrode leads which project from a bottom surface of the outer core perpendicular to central axes of the at least two through holes, wherein the plurality of electrode leads are electrically connected with opposite ends of each of the at least two windings; and
a sealing member which fixes each of the at least two inner cores to a respective through hole of the at least two through holes of the outer core.

2. The multi-inductor of claim 1, wherein each of the at least two inner cores comprises:
a winding portion around which one of the at least two windings is wound; and
a pair of caps covering the winding portion on opposite ends.

3. The multi-inductor of claim 2, wherein the sealing member is provided between an outer circumferential surface of each of the pair of caps of the at least two inner cores and a respective through hole of the outer core.

4. The multi-inductor of claim 1, wherein the plurality of electrode leads are formed by bending a metal plate.

5. The multi-inductor of claim 4, wherein each of the plurality of electrode leads comprises:
a connecting portion which is connected to an end of the bottom wall of the outer core; and
a lead portion which extends from the connecting portion and is perpendicular to the connecting portion.

6. The multi-inductor of claim 5, wherein
the lead portion is a three dimensional element and is formed by bending so that a cross-section of the lead portion cut perpendicular to a lengthwise direction thereof has a two-dimensional shape.

7. The multi-inductor of claim 6, wherein
the cross-section of the lead portion comprises one of a semi-circular shape, a triangular shape, a rectangular shape, and a pentagonal shape.

8. The multi-inductor of claim 5, wherein the electrode lead further comprises a reinforcing portion spaced apart from and extended parallel to the lead portion from the connecting portion.

9. The multi-inductor of claim 5, wherein
the connecting portion projects outside of the outer core forming a projecting portion to which a lead end of one of the at least two windings is connected.

10. The multi-inductor of claim 1, wherein
the outer core comprises an extending portion which is extended in a lengthwise direction of a respective inner core of the at least two inner cores from the top wall and which has a length longer than the at least two inner cores.

11. The multi-inductor of claim 10, wherein
the outer core further comprises a supporting portion which supports the extending portion.

12. A slim flat image display apparatus comprising:
a frame;
an image display module provided inside the frame;
a power board provided inside the frame and which supplies power to the image display module;
a rear cover which covers the power board; and
a multi-inductor provided on the power board and which is adjacent to an inner surface of the rear cover,
wherein the multi-inductor comprises:
an outer core with at least two through holes being formed therein in a horizontal direction;
at least two inner cores respectively provided in the at least two through holes;
at least two windings respectively wound around an outer circumferential surface of a respective core of the at least two inner cores;
a plurality of electrode leads which project from a bottom surface of the outer core perpendicular to central axes of the at least two through holes, the plurality of electrode leads are electrically connected with opposite ends of each of the at least two windings; and
a sealing member which fixes each of the at least two inner cores to a respective through hole of the at least two through holes of the outer core.

13. The multi-inductor of claim 1, wherein the multi-inductor is positioned in the slim flat image display apparatus.

14. The multi-inductor of claim 1, further comprising extension portions which are provided on both ends of an outer core so as to extend in a lengthwise direction of the at least two inner cores.

15. The multi-inductor of claim 14, where the extension portions extends a top wall of the outer core placed above a respective inner core with a gap there between.

16. The multi-inductor of claim 15, wherein the respective inner core comprises a pair of caps covering a respective winding in the respective inner core on both ends and wherein the gap is provided above each of the pair of caps.

17. The multi-inductor of claim 1, wherein a top wall of the outer core is longer in a lengthwise direction than a bottom wall of the outer core.

18. A multi-inductor comprising:
an outer core with at least two through holes being formed therein;
at least two inner cores respectively provided in a respective through hole of the at least two through holes;
at least two windings respectively wound around a respective core of the at least two inner cores; and
a plurality of electrode leads which project from a bottom surface of the outer core perpendicular to central axes of the at least two through holes, the plurality of electrode leads are electrically connected with opposite ends of each of the at least two windings,
wherein a top wall of the outer core is longer than a bottom wall of the outer core.

19. The multi-inductor of claim 18, wherein the top wall of the outer core is reinforced by a plurality of supporting members which are positioned at an inclined angle and which extend from the electrode leads to the top wall.

20. The multi-inductor of claim 18, wherein the electrode leads comprise a clamping portion and an extending portion, wherein the clamping portion fixes the electrode leads to the bottom wall of the outer core and the extending portions are bend into a three dimensional shape.
